(19) United States
(12) Patent Application Publication
(10) Pub. No.: US 2024/0410082 A1
(43) Pub. Date: Dec. 12, 2024

(54) SUPERLATTICE STRUCTURE AND MANUFACTURING METHOD THEREFOR

(71) Applicant: Nippon Telegraph and Telephone Corporation, Tokyo (JP)

(72) Inventors: Ai Ikeda, Tokyo (JP); Yoshiharu Krockenberger, Tokyo (JP); Yoshitaka Taniyasu, Tokyo (JP); Hideki Yamamoto, Tokyo (JP)

(21) Appl. No.: 18/697,886

(22) PCT Filed: Nov. 22, 2021
(86) PCT No.: PCT/JP2021/042760

§ 371 Date: Apr. 2, 2024

(51) Int. Cl. C30B 29/68; C30B 25/16; C30B 25/18; C30B 29/22; C30B 33/00

(52) U.S. Cl. CPC C30B 29/68; C30B 25/16; C30B 25/18; C30B 29/22; C30B 33/005

(57) ABSTRACT

Provided is a superlattice structure in which a first crystal layer having a unit lattice of Ca₂Fe₂O₅ with a brownmillerite structure and a second crystal layer having a unit lattice of CaCuO₂ with an infinite layer structure are alternately stacked. The thickness of the first crystal layer is a critical film thickness at which the first crystal layer is able to coherently grow on the second crystal layer. In this superlattice structure, the first crystal layer as the lowermost layer is formed on and in contact with a single crystal substrate, and the second crystal layer and the first crystal layer are alternately stacked on the first crystal layer formed on and in contact with the single crystal substrate.

### CROSS-REFERENCE TO RELATED APPLICATIONS

This application is a national phase entry of PCT Application No. PCT/JP2021/042760, filed on Nov. 22, 2021, which application is hereby incorporated herein by reference.

### TECHNICAL FIELD

The present invention relates to a superlattice structure and a method for fabricating the same.

### BACKGROUND

Cuprate high-temperature superconductors are a group of substances that exhibit a superconducting transition temperature higher than the boiling point of liquid nitrogen (77 K=about −196° C.) under normal pressure. Since nitrogen is abundantly contained in the atmosphere and is inexpensive, cuprate high-temperature superconductors are expected to be materials for (1) lossless supply and distribution, (2) a strong magnetic field magnet, and (3) next-generation ultrahigh-sensitivity sensors, which can be used by cooling with liquid nitrogen.

All the cuprate high-temperature superconductors have a layered structure in which a plurality of types of single layers composed of cationic metal elements and anionic elements (mainly oxygen) are regularly stacked. The configuration and coordination of elements in each layer vary depending on the crystal structure, but at least one or more of the layers include a layer called a CuO₂ plane composed of copper and oxygen, and superconductivity is exhibited in this layer.

In the related art, studies on novel substances exhibiting superconductivity (metallicity) in cuprates have been conducted by comprehensively conducting studies under various conditions as described below. First, under thermodynamic equilibrium conditions, the combination of elements other than copper and oxygen is changed under synthesis conditions allowing a layered structure (spontaneous superlattice structure) in which layers composed of cationic elements and anionic elements are regularly stacked as described above, and conditions such as raw materials, their composition, a reaction temperature, and a reaction atmosphere are systematically changed.

Cuprate high-temperature superconductors having a superconducting transition temperature equal to or higher than the temperature of liquid nitrogen found so far are oxides containing four or more elements. Therefore, in order to synthesize a new substance having a spontaneous superlattice structure in which impurity phases are not mixed in under the thermodynamic equilibrium conditions as described above, it is necessary to control the composition ratio of the raw materials, the synthesis temperature, and the like extremely precisely. Therefore, there are limits when searching for new substances by the approach of fabricating a spontaneous superlattice.

### CITATION LIST

### Non Patent Literature

Non Patent Literature 1: Y. Krockenberger et al., “Infinite-layer phase formation in the Ca1-xSrxCuO2 system by reactive molecular beam epitaxy”, Journal of Applied Physics, vol. 124, no. 7, 073905, 2018.
Non Patent Literature 2: A. Ikeda et al., “Molecular beam epitaxy of electron-doped infinite-layer Ca1-xRxCuO2 thin film”, Physical Review Materials, vol. 3, no. 6, 064803, 2019.
Non Patent Literature 3: N. Kobayashi et al., “Compounds and Phase Relations in the SrO—CaO—CuO System under High Pressure”, Journal of Solid State Chemistry, vol. 132, pp. 274-283, 1997.
Non Patent Literature 4: D. Di Castro et al., “Occurrence of a high-temperature superconducting phase in (CaCuO2)n/(SrTiO3)m superlattices”, Physical Review B, vol. 86, no. 13, 134524, 2012.

### SUMMARY

### Technical Problem

Incidentally, in order to fabricate a superconducting wire material or a device that can be used by being cooled with liquid nitrogen (77 K), it is desirable that the superconducting transition temperature of the material be sufficiently higher than 77 K and have a sufficient margin. As described above, cuprate superconductors include a layer called a CuO₂ plane. More specifically, among the cuprate superconductors found so far, those having a superconducting transition temperature exceeding 100 K commonly include a CaCuO₂ layer (containing calcium and copper as cationic metal elements and oxygen as anionic elements).

The CaCuO₂ layer has a special crystal structure called an “infinite layer structure”, and a substance called CaCuO₂ having this crystal structure cannot be synthesized under synthesis conditions under normal pressure (Non Patent Literature 1). However, the CaCuO₂ layer can be synthesized as a single oxide “infinite layer structure CaCuO₂” by high-pressure synthesis or thin film synthesis using epitaxy. In particular, in thin film synthesis using epitaxy, it is possible to form a single crystal thin film in which an impurity phase is not mixed in and crystal directions are aligned (Non Patent Literature 2). As shown in FIG. 5, CaCuO₂ has a simple crystal structure as compared with multicomponent cuprates (Non Patent Literature 3).

CaCuO₂ itself is an insulator through which no electricity flows, but in a previous research example, there has been a report that superconductivity is exhibited by fabricating a heterostructure of a CaCuO₂ thin film layer which is an insulator and a SrTiO₃ thin film layer which is also an insulator, or an artificial superlattice structure (Non Patent Literature 4).

A crystal structure of an existing cuprate high-temperature superconductor having a superconducting transition temperature of 100 K or higher is a spontaneous superlattice structure of a CaCuO₂ layer and a heterogeneous oxide layer. On the other hand, a structure in which CaCuO₂ layers and SrTiO₃ layers are alternately stacked can be regarded as an artificial superlattice structure. However, in an artificial superlattice structure of a CaCuO₂ layer and a copper-free oxide layer, the metallicity and superconductivity have been found only when the copper-free oxide layer is ATiO₃ (A=Sr, Ca).

As described above, in the related art, there has been a problem that there are few types of artificial superlattice structures from which superconductivity is obtained by the CaCuO₂ layer and the copper-free oxide layer, and there are few options for artificial superlattice structures from which superconductivity is obtained.

Embodiments of the present invention have been made to solve the above problems, and an object of embodiments of the present invention is to increase the number of options for an artificial superlattice structure in which superconductivity by a CaCuO₂ layer and a copper-free oxide layer can be obtained.

### Solution to Problem

According to embodiments of the present invention, there is provided a superlattice structure in which a first crystal layer having a unit lattice of Ca₂Fe₂O₅ with a brownmillerite structure and a second crystal layer having a unit lattice of CaCuO₂ with an infinite layer structure are alternately stacked.

In addition, according to embodiments of the present invention, there is provided a method for fabricating a superlattice structure, including alternately growing, on a single crystal substrate, a first crystal layer having a unit lattice of Ca₂Fe₂O₅ with a brownmillerite structure and a second crystal layer having a unit lattice of CaCuO₂ with an infinite layer structure to fabricate a superlattice structure.

### Advantageous Effects of Embodiments of Invention

As described above, according to embodiments of the present invention, the first crystal layer having a unit lattice of Ca₂Fe₂O₅ with a brownmillerite structure and the second crystal layer having a unit lattice of CaCuO₂ with an infinite layer structure are alternately stacked. Therefore, it is possible to increase the number of options for an artificial superlattice structure capable of obtaining superconductivity by a CaCuO₂layer and a copper-free oxide layer.

### BRIEF DESCRIPTION OF THE DRAWINGS

FIG. 1 is a cross-sectional view illustrating a configuration of a superlattice structure of embodiments of the present invention.

FIG. 2 is a perspective view illustrating a crystal structure of a brownmillerite structure Ca₂Fe₂O₅.

FIG. 3 is a characteristic diagram illustrating the temperature dependence of the electrical resistivity of two types of [(CaCuO₂)ₙ/(Ca₂Fe₂O₅)ₘ]^{N} artificial superlattices fabricated by setting a thickness t1 of a first crystal layer 101 and a thickness t2 of a second crystal layer 102 to (a) (t1, t2)=(1.8 nm, 4 nm) and (b) (t1, t2)=(1.4 nm, 4 nm). The temperature of the superlattice structure is lowered from the fabrication temperature to Tₒₓ=140° C. while irradiating the surface with atomic oxygen.

FIG. 4 is a characteristic diagram illustrating the temperature dependence of the electrical resistivity of a [(CaCuO₂)ₙ/(Ca₂Fe₂O₅)ₘ]^{N} artificial superlattice fabricated by setting the thickness t1 of the first crystal layer 101 and the thickness t2 of the second crystal layer 102 to (t1, t2)=(1.4 nm, 4 nm). The superlattice structure is compared between (a) a case where the temperature is lowered from the fabrication temperature to Tₒₓ, =200° C. while atomic oxygen is radiated and (b) a case where the temperature is lowered in a vacuum.

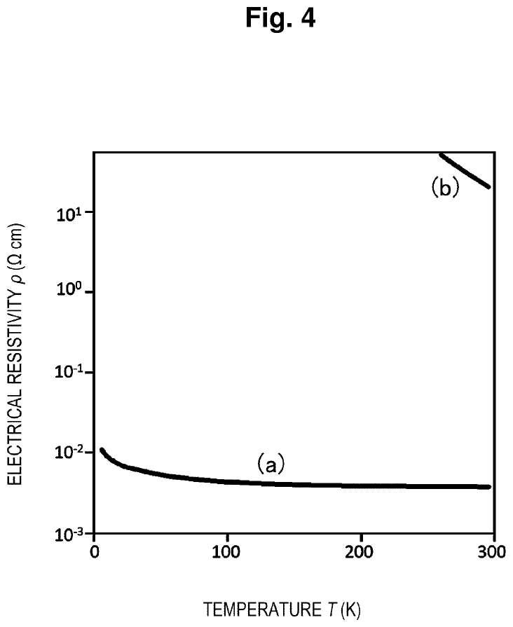

FIG. 5 is a perspective view illustrating a crystal structure of CaCuO₂ with an infinite layer structure.

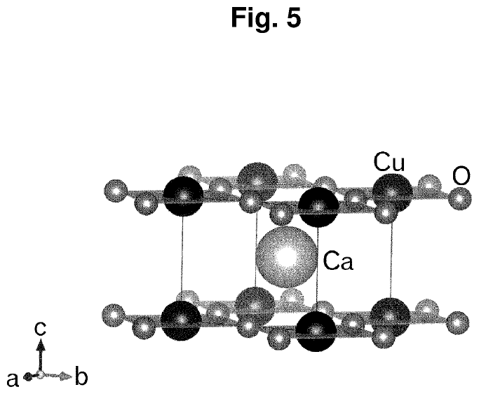

### DETAILED DESCRIPTION OF ILLUSTRATIVE EMBODIMENTS

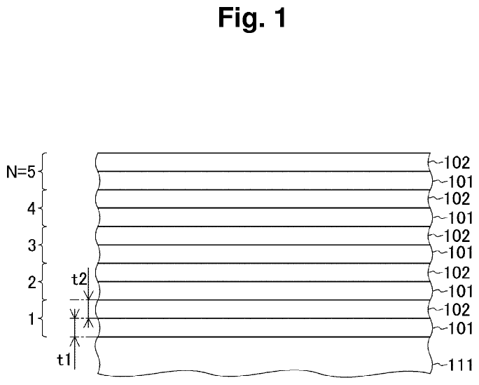

A superlattice structure according to an embodiment of the present invention will be described below with reference to FIG. 1. In this superlattice structure, a first crystal layer 101 having a unit lattice of Ca₂Fe₂O₅ with a brownmillerite structure and a second crystal layer 102 having a unit lattice of CaCuO₂ with an infinite layer structure are alternately stacked.

Here, it is important that the thickness of the first crystal layer 101 is a critical film thickness at which the first crystal layer 101 is able to coherently grow on the second crystal layer 102. In this superlattice structure, the first crystal layer 101 as the lowermost layer is formed on and in contact with a single crystal substrate in, and the second crystal layer 102 and the first crystal layer 101 are alternately stacked on the first crystal layer 101 formed on and in contact with the single crystal substrate in. The single crystal substrate 111 can be composed of (LaAlO₃)_{0.3}(SrAl_{0.5}Ta_{0.5}0₃)_{0.7}.

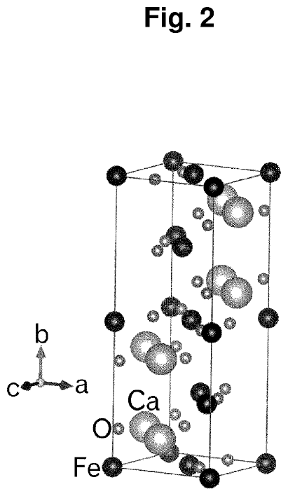

FIG. 1 illustrates a schematic diagram of a [(CaCuO₂)ₙ/(Ca₂Fe₂O₅)ₘ]^{N} superlattice structure in which the first crystal layer 101 and the second crystal layer 102 are alternately stacked. Note that, in [(CaCuO₂)ₙ/(Ca₂Fe₂O₅)ₘ]^{N}, n is the number of unit lattices (crystal lattices) of CaCuO₂ contained in one second crystal layer 102, and m is the number of pseudo perovskite unit lattices of Ca₂Fe₂O₅ contained in one first crystal layer 101 when the crystal structure is regarded as a pseudo perovskite structure. In addition, FIG. 2 illustrates a crystal structure of the brownmillerite structure Ca₂Fe₂O₅.

Next, a method for fabricating a superlattice structure according to an embodiment of the present invention will be described. In this fabrication method, the first crystal layer 101 having a unit lattice of Ca₂Fe₂O₅ with a brownmillerite structure and the second crystal layer 102 having a unit lattice of CaCuO₂ with an infinite layer structure are alternately grown on the single crystal substrate 11 to fabricate a superlattice structure. Here, it is important to form the first crystal layer 101 grown on the second crystal layer 102 to have a critical film thickness at which the first crystal layer 101 is able to coherently grow. Note that “being able to coherently grow” means that the second crystal layer 102 can grow while adjusting its own lattice constant to the lattice constant of the first crystal layer 101.

Furthermore, the first crystal layer 101 and the second crystal layer 102 are alternately grown on the single crystal substrate 11 under a predetermined substrate temperature condition to form a superlattice structure, and then oxygen deficiency of CaCuO₂ responsible for superconductivity in the superlattice structure can be reduced by lowering the temperature while supplying oxygen, and a superconducting transition can be achieved by cooling the obtained superlattice structure to a predetermined temperature.

As a result of intensive studies by the inventors, embodiments of the present invention has been made by finding that superconductivity is exhibited by fabricating the first crystal layer 101 having a unit lattice of Ca₂Fe₂O₅ with a brownmillerite structure as a copper-free oxide layer, and fabricating an artificial superlattice structure by the first crystal layer 101 and the second crystal layer 102 having a unit lattice of infinite layer structure CaCuO₂. The inventors have found exhibition of the above-described superconductivity while intensively carrying out the fabrication of the heterostructure/artificial superlattice structure by alternately stacking the first crystal layer 101 having the brownmillerite structure Ca₂Fe₂O₅ and the second crystal layer 102 having the infinite layer structure CaCuO₂ each with a certain thickness (t1, t2) and repeating the stacking N times.

As described above, by setting the thickness t1 of the first crystal layer 101 to about the critical film thickness at which the first crystal layer 101 is able to coherently grow on the second crystal layer 102, the [(CaCuO₂)ₙ/(Ca₂Fe₂O₅)ₘ]^{N} superlattice becomes superconducting. Under this condition, it is also essential to reduce (suppress) oxygen deficiency in the superlattice structure by continuously supplying oxygen (irradiating with atomic oxygen) from a temperature (about 590° C.) at which the superlattice is fabricated in the ultra-high vacuum device to a temperature lower than 200° C. after the superlattice is fabricated (grown), for achieving superconductivity.

The superlattice structure in which oxygen deficiency is reduced (suppressed) by being fabricated as described above is obtained through a step of alternately growing the first crystal layer 101 and the second crystal layer 102 on the single crystal substrate 111 under a predetermined substrate temperature condition to form a superlattice structure, and then lowering the temperature while supplying oxygen. With this superlattice structure, for example, a superconducting transition is obtained at 50 K or less.

In the superlattice structure of embodiments of the present invention, when Ca₂Fe₂O₅ constituting the first crystal layer 101 and CaCuO₂ constituting the second crystal layer 102 have a stoichiometric composition, a superconducting transition is obtained at a predetermined low temperature state. However, it is considered that even when Ca₂Fe₂O₅ constituting the first crystal layer 101 deviates slightly from the stoichiometric composition due to a very slight excessive oxygen uptake or oxygen deficiency, and CaCuO₂ constituting the second crystal layer 102 deviates slightly from the stoichiometric composition due to a very slight oxygen deficiency, a superconducting transition is obtained. In other words, when excessive oxygen uptake or oxygen deficiency (oxygen vacancy) is in a very small range, a superconducting transition is obtained, and when oxygen vacancy occurs beyond a certain value, a superconducting transition cannot be obtained.

On the other hand, it is known that when copper (Cu), instead of oxygen (O), in a CuO₂ plane which is contained in a layer of CaCuO₂ and is known to be responsible for superconductivity in a cuprate superconductor, as described in the background art, is replaced with a trace amount of nonmagnetic zinc (Zn) which does not destroy superconductivity by magnetic interaction, superconductivity disappears by substitution of about 3% to 4% (Reference Literature 1 and Reference Literature 2). From this, it is reasonably estimated that the oxygen deficiency amount at which superconductivity disappears is about the same (about 3% to 4%).

However, it can be said that it is impossible to specify the state in which the oxygen deficiency in the superlattice structure is suppressed by analysis based on measurement from the analysis technology at the time of filing of the present application. Therefore, for the superlattice structure of embodiments of the present invention, it is considered to be rather impractical to directly specify the superlattice structure by its structure or characteristics, for example, by clearly specifying the degree of oxygen deficiency contributing to the effect of embodiments of the present invention.

### Example

More detailed description will be given below using examples. The [(CaCuO₂)ₙ/(Ca₂Fe₂O₅)ₘ]^{N} superlattice was formed using a molecular beam epitaxy (MBE) method. Ca, Cu, and Fe as metal raw materials were disposed in an ultrahigh vacuum chamber of an MBE apparatus, and an electron beam accelerated to about 10 kV was heated by colliding with each raw material and evaporated, and supplied onto a single crystal substrate disposed at a position facing each other.

In order to oxidize the metal atoms supplied onto the single crystal substrate even under a high vacuum, atomic oxygen (O) having higher activity than molecular oxygen (O₂) and strong oxidizing power was generated and supplied by separating molecular oxygen using a high-frequency plasma source. The generated atomic oxygen is irradiated from the high-frequency plasma source toward the substrate.

In the example, on the single crystal substrate 111 made of (LaAlO₃)_{0.3}(SrAl_{0.5}Ta_{0.5}O₃)_{0.7}(LSAT), the first crystal layer 101 made of Ca₂Fe₂O₅ and the second crystal layer 102 made of CaCuO₂ were alternately stacked with the thickness t1 and the thickness t2, respectively, to form (grow) a [(CaCuO₂)ₙ/(Ca₂Fe₂O₅)ₘ]^{N} superlattice. The substrate temperature during film formation was 590° C.

In the stacking order of the [(CaCuO₂)ₙ/(Ca₂Fe₂O₅)ₘ]^{N} superlattice, first, the first crystal layer 101 made of Ca₂Fe₂O₅ was stacked on a substrate, the second crystal layer 102 made of CaCuO₂ was stacked thereon, and further, the first crystal layer 101, the second crystal layer 102, the first crystal layer 101, . . . were alternately repeated 15 times.

After 15 times of stacking were repeated, only the supply of metal atoms was stopped, and the temperature was lowered while the superlattice surface was irradiated (supplied) with atomic oxygen. The irradiation with atomic oxygen was continued until the substrate temperature decreased to (reached) Tₒₓ=140° C.

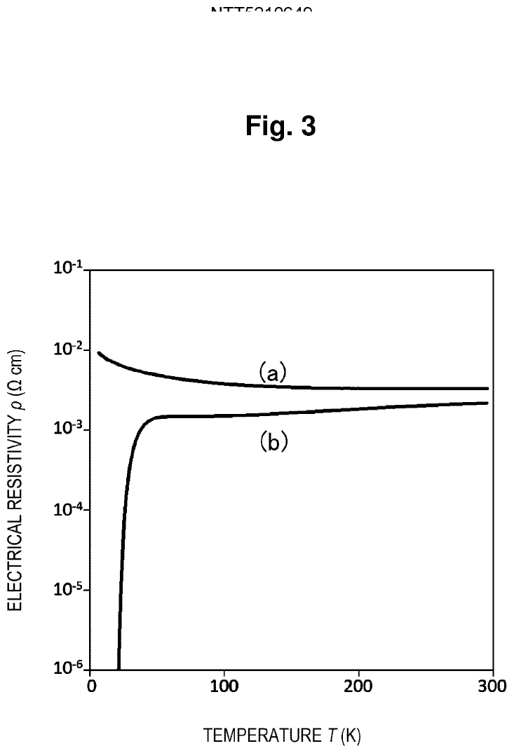

(b) of FIG. 3 illustrates the temperature dependence of the electrical resistivity of a [(CaCuO₂)ₙ/(Ca₂Fe₂O₅)ₘ]^{N} artificial superlattice fabricated by setting the thickness t1 of the first crystal layer 101 and the thickness t2 of the second crystal layer 102 to (t1, t2)=(1.4 nm, 4 nm). For comparison, (a) of FIG. 3 illustrates the temperature dependence of the electrical resistivity of the [(CaCuO₂)ₙ/(Ca₂Fe₂O₅)ₘ]^{N} artificial superlattice of (t1, t2)=(1.8 nm, 4 nm). In the [(CaCuO₂)ₙ/(Ca₂Fe₂O₅)ₘ]^{N} artificial superlattice fabricated with (t1, t2)=(1.4 nm, 4 nm), as illustrated in (b) of FIG. 3, the electrical resistivity decreased from 300 K with decreasing temperature, and showed a superconducting transition at 50 K or less.

The electrical resistivity of a sample obtained by fabricating a [(CaCuO₂)ₙ/(Ca₂Fe₂O₅)ₘ]^{N} artificial superlattice, stacking the artificial superlattice N times, and then cooling (lowering the temperature of) the artificial superlattice in high vacuum without supplying oxygen using the same conditions [(t1, t2)=(1.4 nm, 4 nm)] as (t1, t2) of the artificial superlattice showing the superconducting transition shows a high resistivity exceeding several tens of Ωcm at 300 K and the temperature dependence of the insulator-like resistivity as illustrated in FIG. (b) of 4.

In a state where oxygen (atomic oxygen) is supplied in the temperature lowering process, as illustrated in (b) of FIG. 3, when fabrication is performed under a condition where the lowering temperature Tₒₓ is lower than 200° C., superconductivity is confirmed, and when this condition is satisfied, superconductivity is obtained regardless of Tₒₓ. As illustrated in FIG. (a) of 4, when Tₒₓ=200° C., the resistivity decreases, but superconductivity is not exhibited. In addition, as long as the thickness t2 of the second crystal layer 102 is within a range in which a superlattice structure can be fabricated, the exhibition of superconductivity does not depend on the value of t2. As described above, when the thickness t1 of the first crystal layer 101 is about a critical film thickness t_{c} (t_{c} to 1.5 nm) at which the coherence of the stacked structure is maintained, superconductivity is obtained, and when the thickness t1 is thicker than the critical film thickness tc, superconductivity is not obtained.

By appropriately selecting the thickness t1 of the first crystal layer 101 made of Ca₂Fe₂O₅ and the lowering temperature Tₒₓ in atomic oxygen, metallicity, superconductivity, and insulating properties exhibited by the [(CaCuO₂)ₙ/(Ca₂Fe₂O₅)ₘ]^{N} artificial superlattice can be controlled.

As described above, according to embodiments of the present invention, the first crystal layer having a unit lattice of Ca₂Fe₂O₅ with a brownmillerite structure and the second crystal layer having a unit lattice of CaCuO₂ with an infinite layer structure are alternately stacked. Therefore, it is possible to increase the number of options for an artificial superlattice structure capable of obtaining superconductivity by a CaCuO₂ layer and a copper-free oxide layer. According to embodiments of the present invention, it has been shown that the first crystal layer and the second crystal layer are alternately stacked to achieve superconductivity. Therefore, it is easily estimated that an artificial superlattice structure exhibiting superconductivity can be fabricated by alternately stacking a copper-free oxide other than Ca₂Fe₂O₅ and a CaCuO₂ layer, for example.

According to embodiments of the present invention, it is possible to fabricate a superconductor (metal) of an artificial crystal that does not exist in nature, and a new possibility is presented for practical use of a high-temperature superconducting material. In addition, it is possible to fabricate a new stacked structure material exhibiting metallic and superconductivity in various combinations only by changing oxides to be stacked on the basis of a layer of CaCuO₂, and material selectivity is remarkably improved. In addition, control of the superconducting transition temperature can be expected by selecting a combination of oxides, and further, improvement of the superconducting transition temperature can be expected by optimizing the combination. Therefore, embodiments of the present invention can also be applied to a superconducting device capable of operating at a desired temperature. According to embodiments of the present invention, it can be a breakthrough in designing and actually fabricating a novel high-temperature superconductor more suitable for application.

Note that embodiments of the present invention is not limited to the embodiment described above, and it is obvious that many modifications and combinations can be implemented by a person having ordinary knowledge in the art within the technical idea of the present invention.

Reference Literature 1 J. Sugiyama et al., “Comparison of paramagnetic- and nonmagnetic-impurity effects on superconductivity in Nd1.85Ce0.15CuO4”, Physical Review B, vol. 43, pp. 10489-10495, 1991.

Reference Literature 2 J. M. Tarascon et al., “Magnetic versus nonmagnetic ion substitution effects on Tc in the La—Sr—Cu-o and Nd—Ce—Cu-o systems”, Physical Review B, vol. 42, pp. 218-222, 1990.

### REFERENCE SIGNS LIST

101 First crystal layer
102 Second crystal layer
111 Single crystal substrate

1-8. (canceled)

9. A superlattice structure comprising:
a multi-layer structure comprising one or more first crystal layers alternately stacked with one or more second crystal layers,
wherein each of the one or more first crystal layers has a unit lattice of Ca₂Fe₂O₅ with a brownmillerite structure, and
wherein each of the one or more second crystal layers has a unit lattice of CaCuO₂ with an infinite layer structure.

10. The superlattice structure according to claim 9, wherein a thickness of each of the one or more first crystal layers disposed on the one or more second crystal layers is a film thickness at which each of the one or more first crystal layers is able to coherently grow on the one or more second crystal layers.

11. The superlattice structure according to claim 9,
wherein a first crystal layer of the one or more first crystal layers is in direct contact with a single crystal substrate.

12. The superlattice structure according to claim 11, wherein the single crystal substrate is composed of (LaAlO₃)_{0.3}(SrAl_{0.5}Ta_{0.5}O₃)_{0.7}.

13. The superlattice structure according to claim 12, wherein each of the one or more first crystal layers is made of Ca₂Fe₂O₅, and wherein each of the one or more second crystal layers is made of CaCuO₂.

14. A method for fabricating a superlattice structure, the method comprising:
alternately growing, on a substrate, one or more first crystal layers and one or more second crystal layers, wherein
each of the one or more first crystal layers has a unit lattice of Ca₂Fe₂O₅ with a brownmillerite structure, and
each of the one or more second crystal layers has a unit lattice of CaCuO₂ with an infinite layer structure.

15. The method for fabricating the superlattice structure according to claim 14, wherein each of the one or more first crystal layers grown on the one or more second crystal layers is formed to have a film thickness at which the one or more first crystal layers is able to coherently grow on the one or more second crystal layers.

16. The method for fabricating the superlattice structure according to claim 14, wherein the substrate is a single crystal substrate.

17. The method for fabricating the superlattice structure according to claim 16, wherein the single crystal substrate is composed of (LaAlO₃)_{0.3}(SrAl_{0.5}Ta_{0.5}O₃)_{0.7}.

18. The method for fabricating the superlattice structure according to claim 17, wherein each of the one or more first crystal layers is made of Ca₂Fe₂O₅, and wherein each of the one or more second crystal layers is made of CaCuO₂.

19. The method for fabricating the superlattice structure according to claim 17, wherein a first crystal layer of the one or more first crystal layers is grown directly on the substrate.

20. The method for fabricating the superlattice structure according to claim 19, wherein the one or more first crystal layers and the one or more second crystal layers are alternately grown on the substrate at a predetermined substrate temperature to form the superlattice structure, and wherein oxygen deficiency in the superlattice structure is reduced by lowering a temperature of the superlattice structure below the predetermined substrate temperature while supplying oxygen.

21. The method for fabricating the superlattice structure according to claim 20, wherein the predetermined substrate temperature is 590° C., and wherein the temperature of the super lattice structure is reduced to be lower than 200° C. while supplying oxygen to reduce oxygen deficiency in the super lattice structure.

22. A method for fabricating, the method comprising:
growing, on a substrate, a superlattice structure at a first temperature, wherein growing the superlattice structure comprises alternating growing one or more first crystal layers and one or more second crystal layers at the first temperature, wherein each of the one or more first crystal layers has a unit lattice of Ca₂Fe₂O₅ with a brownmillerite structure, and wherein each of the one or more second crystal layers has a unit lattice of CaCuO₂ with an infinite layer structure; and
reducing oxygen deficiency in the superlattice structure by lowering the first temperature to a second temperature.

23. The method according to claim 22, wherein the first temperature is 590° C., and wherein the second temperature is no more than 200° C.

24. The method according to claim 22, wherein the substrate is made of (LaAlO₃)_{0.3}(SrAl_{0.5}Ta_{0.5}O₃)_{0.7}, wherein each of the one or more first crystal layers is made of Ca₂Fe₂O₅, and wherein each of the one or more second crystal layers is made of CaCuO₂.

25. The method according to claim 22, wherein each of the one or more first crystal layers grown on the one or more second crystal layers is formed to have a film thickness at which the one or more first crystal layers is able to coherently grow on the one or more second crystal layers.
